(19) United States
(12) Patent Application Publication
(10) Pub. No.: US 2026/0190253 A1
(43) Pub. Date: Jul. 2, 2026

(54) DISPLAY DEVICE

(71) Applicant: LG Display Co., Ltd., Seoul (KR)

(72) Inventors: Jungkyu PARK, Seoul (KR); TaeWoo KIM, Paju-si (KR); JunHyung KIM, Paju-si (KR); Kyungjae PARK, Incheon (KR); GeunChang PARK, Paju-si (KR)

(73) Assignee: LG Display Co., Ltd., Seoul (KR)

(21) Appl. No.: 19/432,485

(22) Filed: Dec. 24, 2025

(30) Foreign Application Priority Data
Dec. 31, 2024 (KR) 10-2024-0201814

(51) Int. Cl. H05K 5/02

(52) U.S. Cl. CPC H05K 5/0217

(57) ABSTRACT

A display panel can include a non-bending area and a bending area. The bending area includes a first bending area corresponding to a lateral portion of the non-bending area and a second bending area corresponding to a corner portion of the non-bending area, and a metal plate disposed below the display panel. The metal plate includes a first part corresponding to the non-bending area and a second part corresponding to the bending area. The second part of the metal plate includes a first sub-area corresponding to the first bending area and a second sub-area corresponding to the second bending area, and the second part of the metal plate includes a rim portion. The rim portion includes a first rim portion disposed in the first sub-area and a plurality of second rim portions disposed in the second sub-area.

### CROSS-REFERENCE TO RELATED APPLICATIONS

This application claims priority to Korean Patent Application No. 10-2024-0201814 filed on Dec. 31, 2024, in the Korean Intellectual Property Office, the entire disclosure of which is hereby expressly incorporated by reference into the present application.

### BACKGROUND

### Field

The present disclosure relates to a display device, and more particularly, to a display device with ensured mechanical rigidity.

### Discussion of the Related Art

Recently, display devices, which process and display a large amount of information, have been rapidly developed in accordance with the full-fledged entry into the information era. As display devices used for a monitor of a computer, a TV set, a mobile phone, and the like, there are an organic light-emitting display (OLED) configured to autonomously emit light, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In particular, flexible display devices, which are manufactured to be able to display images even when being bent or folded like paper, have attracted attention as next-generation display devices. The flexible display devices can be classified into an unbreakable display device having high durability and using a plastic thin-film transistor substrate instead of a glass substrate, a bendable display device capable of being bent without being broken, a rollable display device capable of being rolled circularly, and a foldable device capable of being folded. These flexible display devices can have spatial utilization and advantageous interior and design and be applied to various application fields.

Meanwhile, a flat shape of a central portion of a display panel including a bending area needs to be maintained, and a bent shape of a lateral portion including a corner needs to be maintained. Therefore, the display panel may not be smoothly contracted because of contraction deformation occurring on a structure for supporting a shape of a bending area of the display panel, which can cause a problem in which creases are formed, damage occurs, and display quality of the display panel deteriorates.

### SUMMARY OF THE DISCLOSURE

An object to be achieved by the present disclosure is to provide a display device that includes a bending area and can inhibit a metal plate from being wrinkled by compressive stress applied to a corner area.

Another object to be achieved by the present disclosure is to provide a display device capable of improving bending properties while improving mechanical rigidity of a metal plate in a bending area.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device includes a display panel comprising a non-bending area and a bending area and a metal plate disposed below the display panel. The bending area includes a first bending area corresponding to a lateral portion of the non-bending area and a second bending area corresponding to a corner of the non-bending area. The metal plate includes a first part disposed in the non-bending area and a second part disposed in the bending area. The second part includes a plurality of first rim portions disposed in the first bending area and a plurality of second rim portions disposed in the second bending area. The plurality of second rim portions is disposed to be spaced apart from one another in at least one second bending area.

According to another aspect of the present disclosure, there is provided a display device. The display device includes a display panel comprising a non-bending area and a bending area and a metal plate disposed below the display panel. The bending area includes a first bending area corresponding to a lateral portion of the non-bending area and a second bending area corresponding to a corner of the non-bending area. The metal plate includes a first part disposed in the non-bending area and a second part disposed in the bending area. The second part includes a plurality of first sub-areas disposed in the first bending area and a plurality of second sub-areas disposed in the second bending area. The second part includes a plurality of first rim portions disposed in the plurality of first sub-areas and a plurality of second rim portions disposed in the plurality of second sub-areas. One first rim portion is disposed in each of the plurality of first sub-areas and the number of second rim portions is larger than the number of first rim portions.

According to an aspect of the present disclosure, there is provided a display device. The display device includes a display panel comprising a non-bending area and a bending area, the bending area comprising a first bending area corresponding to a lateral portion of the non-bending area and a second bending area corresponding to a corner of the non-bending area; and a metal plate disposed below the display panel, the metal plate comprising a first part corresponding to the non-bending area and a second part corresponding to the bending area, wherein the second part comprises a first sub-area corresponding to the first bending area and a second sub-area corresponding to the second bending area, and wherein the second part comprises a rim portion, and the rim portion comprises a first rim portion disposed in the first sub-area and a plurality of second rim portions disposed in the second sub-area.

Other detailed matters of the example embodiments of the present disclosure are included in the detailed description and the drawings.

According to the embodiments of the present disclosure, the plurality of rim portions of the metal plate is disposed at the corner of the display device (in some examples, the plurality of rim portions can be spaced apart from one another), which can suppress or prevent the occurrence of a defect, such as a wrinkle of the metal plate, even though compressive stress is concentrated.

According to the embodiments of the present disclosure, the upper pattern and the lower pattern of the metal plate have different shapes, which can ensure bending properties while improving mechanical rigidity.

According to the embodiments of the present disclosure, the occurrence of tearing which may be caused by the protective film is suppressed or prevented during the process of applying the metal plate to the display device, such that it is possible to reduce production energy affected by a tearing defect and optimize the process.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view of a display device according to embodiments of the present disclosure;

FIG. 2 is an enlarged view of area X in FIG. 1;

FIG. 3 is a schematic exploded perspective view of the display device according to the embodiments of the present disclosure;

FIG. 4 is a cross-sectional view taken along line A-B in FIG. 3;

FIG. 5 is a cross-sectional view taken along line C-D in FIG. 3;

FIG. 6 is an enlarged view of area Y in FIG. 3;

FIG. 7 is an enlarged view illustrating a second rim portion and some of a plurality of sub-connection portions of a metal plate according to embodiments of the present disclosure;

FIG. 8 is a view illustrating a part of a top surface of a connection portion disposed in a second sub-area of a second part of the metal plate included in the display device according to the embodiments of the present disclosure;

FIG. 9 is a view illustrating a part of a rear surface of the connection portion disposed in the second sub-area of the second part of the metal plate included in the display device according to the embodiments of the present disclosure;

FIG. 10 is a cross-sectional view taken along line E-F in FIG. 8; and

FIG. 11 is a cross-sectional view taken along line G-H in FIG. 6.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, the element or layer can be disposed directly on the other element or layer or another layer or another element can be interposed therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure. Further, the term “can” fully encompasses all the meanings and coverages of the term “may” and vice versa.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device/apparatus according to all embodiments of the present disclosure are operatively coupled and configured.

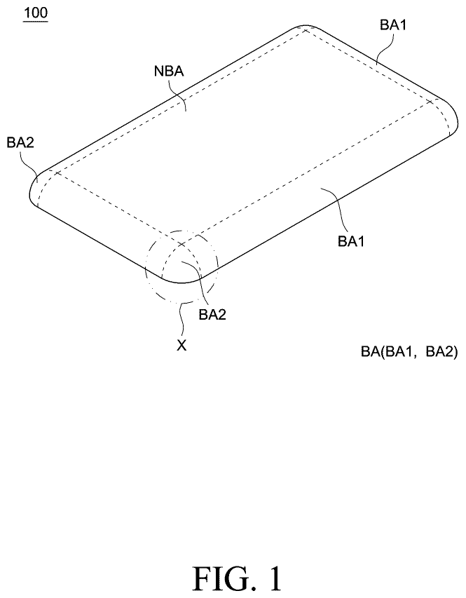

FIG. 1 is a schematic perspective view of a display device according to an embodiment of the present disclosure.

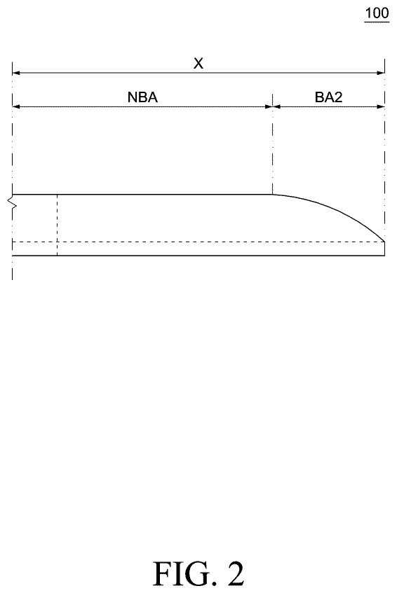

FIG. 2 is an enlarged view of area X in FIG. 1.

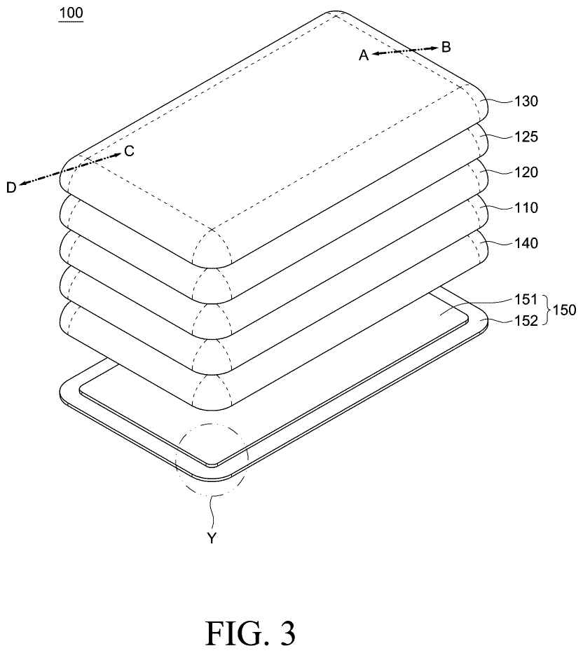

FIG. 3 is a schematic exploded perspective view of the display device according to the embodiment of the present disclosure.

With reference to FIGS. 1 to 3, a display device 100 according to an embodiment of the present disclosure includes a display panel 110, a polarizing film 120, a bonding layer 125, a cover window 130, a backplate 140, and a metal plate 150.

The display panel 110 is a panel for implementing images. Display elements for implementing images, circuit parts for operating the display elements, and the like can be disposed on the display panel 110. For example, in case that the display device 100 is an organic light-emitting display device, the display elements can include an organic light-emitting element.

Hereinafter, for convenience of description, it is assumed that the display device 100 according to the embodiment of the present disclosure is a display device including an organic light-emitting element. However, the present disclosure is not limited thereto.

The circuit part can include various thin-film transistors, capacitors, lines, drive ICs, and the like for operating the organic light-emitting elements.

For example, the circuit parts can include various components such as thin-film driving transistors, thin-film switching transistors, storage capacitors, gate lines, data lines, gate driver integrated circuits (ICs), and data driver ICs. However, the present disclosure is not limited thereto.

The display panel 110 is made by forming the thin-film driving transistors and the light-emitting elements on a flexible substrate and encapsulating the flexible substrate with an encapsulation part. The display panel 110 can include a flexible substrate having a very small thickness for implementing flexibility, and a display element disposed on the flexible substrate.

The flexible substrate can be made of an insulating material having flexibility. For example, the flexible substrate can be an insulating plastic substrate made of a material selected from polyimide, polyether sulfone, polyethylene terephthalate, and polycarbonate.

With reference to FIGS. 1 to 3, the display panel 110 includes a non-bending area NBA and bending areas BA.

The non-bending area NBA is an area in which the display panel 110 is kept in a flat state. The entire non-bending area NBA can be configured as a display area. Alternatively, the non-bending area NBA can include a display area, and a non-display area configured to surround the display area. However, the present disclosure is not limited thereto.

The bending areas BA are areas in which the display panel 110 is bent.

The bending areas BA can be areas extending from lateral portions and corners of the non-bending area NBA.

All or some of the bending areas BA can be configured as the display areas, and a partial area of the bending area BA can be configured as the non-display area. However, the present disclosure is not limited thereto.

The bending areas BA can include first bending areas BA1 and second bending areas BA2.

The first bending area BA1 can be an area extending from the lateral portion of the non-bending area NBA.

The second bending area BA2 can be an area extending from the corner of the non-bending area NBA.

Specifically, in case that the non-bending area NBA has a quadrangular shape in a plan view, the first bending areas BA1 can be areas extending from four sides of the non-bending area NBA and bent at a particular radius of curvature.

In addition, in case that the non-bending area NBA has a quadrangular shape in a plan view, the second bending areas BA2 can be areas extending from four corners and bent at a particular radius of curvature.

The first bending areas BA1 and the second bending areas BA2 can be disposed to surround the non-bending area NBA.

In addition, the first bending areas BA1 and the second bending areas BA2 can be disposed alternately. For example, for example, one second bending area BA2 can be disposed between two first bending areas BA1, and one first bending area BA1 can be disposed between two second bending areas BA2.

Meanwhile, the display device 100 according to the embodiment of the present disclosure can include the display area and the non-display area.

The display area is an area in which a plurality of pixels is disposed to substantially display images.

The non-display area can be disposed to surround the display area.

The non-display area is an area in which no image is substantially displayed. Various lines, a drive IC, a printed circuit board, and the like are disposed to operate the pixel and a drive circuit disposed in the display area. For example, various ICs, such as a gate driver IC and a data driver IC, a VSS line, and the like can be disposed in the non-display area.

Assuming that an image display surface of the display device 100 is directed forward, the polarizing film 120 can be disposed on a display surface of the display panel 110 in a direction toward the display surface of the display device 100.

The polarizing film 120 can serve to polarize, at a polarization angle, light emitted from the display panel 110.

The polarizing film 120 discharges the light, which is polarized at a polarization angle, to the outside. The polarizing film 120 can include a function of blocking the reflection of light beams, except for the light beams polarized at a polarization angle, among light beams from the outside.

Meanwhile, FIG. 3 illustrates that the display device 100 includes the polarizing film 120. However, the polarizing film 120 can be excluded in accordance with design.

The bonding layer 125 can be disposed on the polarizing film 120. The bonding layer 125 can include a transparent bonding material with high light transmittance.

The cover window 130 can be disposed on the bonding layer 125.

The cover window 130 can serve to protect the display panel 110 from external impact and suppress the occurrence of damage such as scratches.

The cover window 130 can be made of a flexible plastic-based material that is bendable to implement the thin, flexible display device 100.

Meanwhile, referring to FIG. 2, a touch panel, which selectively implements a touch sensor, as necessary, can be disposed between the display panel 110 and the cover window 130.

A rear surface of the display panel 110 can include the backplate 140 configured to support the display panel 110. The backplate 140 can be referred to as a top plate because the backplate 140 is one of the two plates disposed on the rear surface of the display panel 110, and the backplate 140 is disposed at the upper side. The backplate 140 can be made of a polyethylene terephthalate (PET) based material.

The backplate 140 can maintain a constant curvature of the display panel 110 and suppress the occurrence of crease on a top surface of the display panel 110 when the display device 100 is bent.

In addition, the backplate 140 can be disposed between the display panel 110 and the metal plate 150 and inhibit a plurality of opening portions of the metal plate 150 from being transferred to a display screen or suppress distortion of the display screen caused by the plurality of opening portions.

The metal plate 150 configured to support the display panel 110 can be disposed on the rear surface of the backplate 140.

The metal plate 150 can serve to support a flexible substrate, which constitutes the display panel 110, so that the flexible substrate does not sag. The metal plate 150 can serve to protect the constituent elements disposed on the flexible substrate from outside moisture, heat, impact, or the like.

The metal plate 150 can be referred to as a bottom plate because the metal plate 150 is one of the two plates disposed on the rear surface of the display panel 110, and the metal plate 150 is disposed at the lower side.

The metal plate 150 can be made of a material such as stainless steel (SUS) and amorphous metal having rigidity to maintain a shape of the display panel 110.

The metal plate 150 can include a first part 151 and a second part 152.

The first part 151 of the metal plate 150 can be a part corresponding to the non-bending area NBA of the display device 100.

The second part 152 of the metal plate 150 can be a part corresponding to the bending area BA of the display device 100. Specifically, the second part 152 of the metal plate 150 can correspond to the first bending area BA1 and the second bending area BA2 of the display device 100.

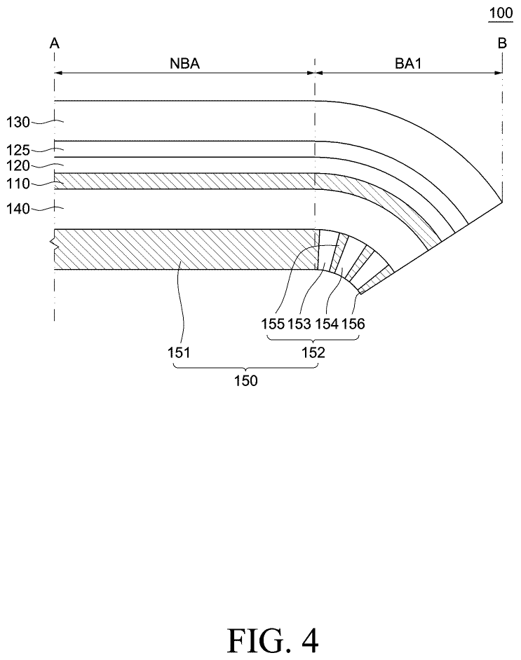

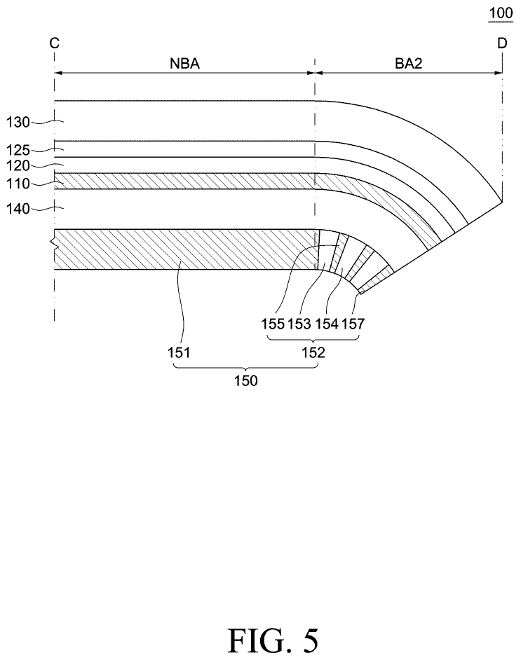

Next, a structure of the display device 100 according to the embodiment of the present disclosure will be described specifically with reference to FIGS. 4 and 5.

FIG. 4 is a cross-sectional view taken along line A-B in FIG. 3.

FIG. 5 is a cross-sectional view taken along line C-D in FIG. 3.

With reference to FIGS. 4 and 5, the display device 100 can include the backplate 140 disposed on the metal plate 150, the display panel 110 disposed on the backplate 140, the polarizing film 120 disposed on the display panel 110, the bonding layer 125 disposed on the polarizing film 120, and the cover window 130 disposed on the bonding layer 125.

The metal plate 150 can include the first part 151 and the second part 152.

A top surface of the first part 151 of the metal plate 150 can have a flat shape.

The second part 152 of the metal plate 150 can include a plurality of first opening portions 153, a plurality of second opening portions 154, connection portions 155, and rim portions 156 and 157.

The plurality of first opening portions 153, the plurality of second opening portions 154, the connection portions 155, first rim portions 156, and a plurality of second rim portions 157 included in the second part 152 can be disposed in the bending area BA of the display device 100.

Specifically, the plurality of first opening portions 153, the plurality of second opening portions 154, the connection portions 155, and the first rim portion 156 included in the second part 152 of the metal plate 150 can be disposed in the first bending area BA1.

The plurality of first opening portions 153, the plurality of second opening portions 154, the connection portions 155, and the plurality of second rim portions 157 included in the second part of the metal plate 150 can be disposed in the second bending area BA2.

In the second part 152 of the metal plate 150, the plurality of first opening portions 153 and the plurality of second opening portions 154 can be disposed to be spaced apart from one another.

The second part 152 of the metal plate 150 can have a shape in which the connection portions 155 are disposed between the plurality of first opening portions 153 and the plurality of second opening portions 154. The connection portions 155 of the second part 152 of the metal plate 150 can be integrated.

As described above, the plurality of first opening portions 153 and the plurality of second opening portions 154 are disposed in the second part 152 of the metal plate 150, such that the metal plate 150 can be easily bent in the bending area BA. However, the present application is not limited thereto. For example, in some embodiments, the second part 152 of the metal plate 150 may not be provided with an opening portion, for example, the second part 152 can be processed in another way to facilitate bending.

In addition, the plurality of first opening portions 153 and the plurality of second opening portions 154 are disposed in the second part 152 of the metal plate 150, such that stress to be applied to the boundary between the first part 151 and the second part 152 of the metal plate 150 can be reduced, which can suppress the occurrence of a rapid change in rigidity of the metal plate 150.

The structure of the metal plate 150 of the display device 100 according to the embodiment of the present disclosure will be described specifically.

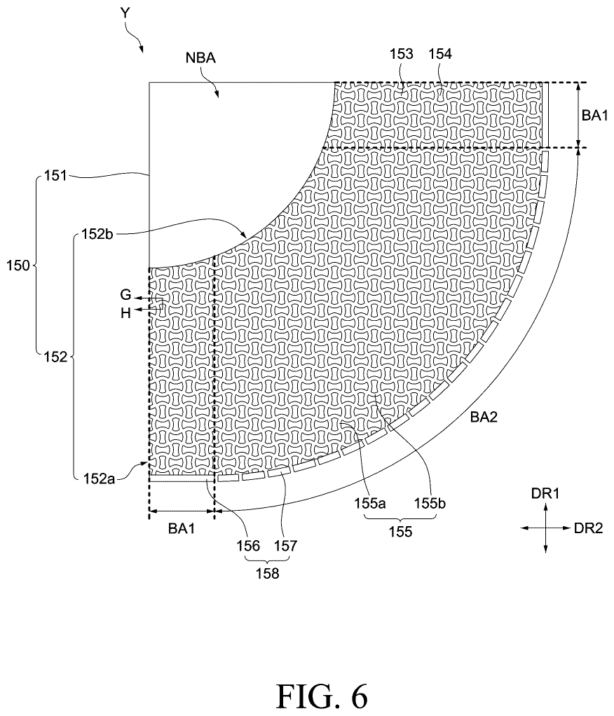

FIG. 6 is an enlarged view of area Y in FIG. 3.

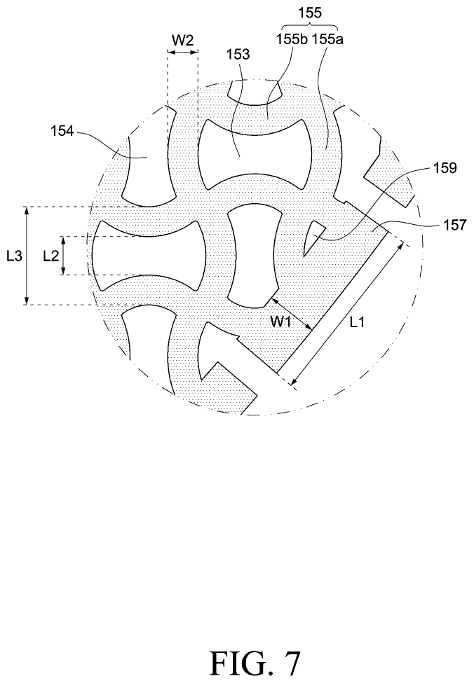

FIG. 7 is an enlarged view illustrating the second rim portion and some of a plurality of sub-connection portions of the metal plate.

With reference to FIGS. 6 and 7, the metal plate 150 of the display device 100 can include the first part 151 and the second part 152.

The first part 151 of the metal plate 150 can be a part corresponding to the non-bending area NBA of the display device 100.

Therefore, the first part 151 of the metal plate 150 can include an area kept in a flat state. For example, the first part 151 of the metal plate 150 can include an area that is not bent at a particular radius of curvature.

The second part 152 of the metal plate 150 can be a part corresponding to the bending area BA of the display device 100.

The second part 152 of the metal plate 150 can include first sub-areas 152a and second sub-areas 152b.

The first sub-area 152a of the second part 152 can be disposed to correspond to the first bending area BA1 of the bending area BA.

In addition, the second sub-area 152b of the second part 152 can be disposed to correspond to the second bending area BA2 of the bending area BA.

Therefore, the first sub-areas 152a and the second sub-areas 152b can be disposed alternately. For example, one second sub-area 152b can be disposed between two first sub-areas 152a, and one first sub-area 152a can be disposed between two second sub-areas 152b.

The second part 152 of the metal plate 150 can extend from the first part 151 and be integrated with the first part 151.

Specifically, in case that the first part 151 of the metal plate 150 has a quadrangular shape in a plan view, the first sub-areas 152a of the second part 152 of the metal plate 150 can extend from four sides of the first part 151 of the metal plate 150.

In addition, in case that the first part 151 of the metal plate 150 has a quadrangular shape in a plan view, the second sub-areas 152b of the second part 152 of the metal plate 150 can extend from the corners of the first part 151 of the metal plate 150.

The second part 152 of the metal plate 150 can include the plurality of first opening portions 153, the plurality of second opening portions 154, the connection portions 155, and rim portions 158.

Specifically, the first sub-area 152a of the second part 152 of the metal plate 150 can include the plurality of first opening portions 153, the plurality of second opening portions 154, the connection portions 155, and the first rim portions 156.

The second sub-area 152b of the second part 152 of the metal plate 150 can include the plurality of first opening portions 153, the plurality of second opening portions 154, the connection portions 155, and the second rim portions 157.

In addition, the second part 152 of the metal plate 150 can further include a plurality of additional opening portions 159 in addition to the plurality of first opening portions 153 and the plurality of second opening portions 154.

The plurality of additional opening portions 159 can be positioned in an area, in which the connection portion 155 and the first part 151 are connected, and positioned at a portion where the connection portion 155 and the rim portion 158 are connected.

The plurality of additional opening portions 159 can be different in shapes from the plurality of first opening portions 153 and the plurality of second opening portions 154. For example, in a plan view, the plurality of additional opening portions 159 can each have a closed curved shape or a curved shape partially opened.

In a portion where the first part 151 and the connection portion 155 of the metal plate 150 are connected, a margin can be required to connect the first opening portion 153 and the second opening portion 154 of the second part 152 while maintaining the shapes of the first opening portion 153 and the second opening portion 154.

However, a part of the portion where the first part 151 and the connection portion 155 of the metal plate 150 are connected can have an insufficient margin required to connect the connection portion 155 to the first part 151 while maintaining the shapes of the first opening portion 153 and the second opening portion 154. The plurality of additional opening portions 159 can be disposed at the portions where the margin is insufficient.

Likewise, a part of a portion where the rim portion 158 and the connection portion 155 of the metal plate 150 are connected can have an insufficient margin required to connect the connection portion 155 to the rim portion 158 while maintaining the shape of the first opening portion 153 or the second opening portion 154. The plurality of additional opening portions 159 can be disposed at the portions where the margin is insufficient.

The plurality of first opening portions 153 and the plurality of second opening portions 154 disposed in the first sub-area 152a and the second sub-area 152b of the second part 152 of the metal plate 150 can be disposed alternately in a first direction DR1 and a second direction DR2 intersecting the first direction DR1. For example, the first direction DR1 can be perpendicular to the second direction DR2, but the present disclosure is not limited thereto.

The planar shape of each of the plurality of first opening portions 153 can have an outer peripheral shape having two opposite sides convex in one direction and two opposite sides concave in another direction intersecting one direction.

The planar shape of each of the plurality of second opening portions 154 can be identical to a shape in which the first opening portion 153 is rotated by 90°.

Specifically, the planar shape of the plurality of second opening portions 154 can have an outer peripheral shape having two opposite sides concave in one direction and two opposite sides convex in another direction intersecting one direction.

For example, as illustrated in FIG. 6, two opposite sides of each of the plurality of first opening portions 153 based on the second direction DR2 can have convex outer peripheral shapes, and two opposite sides of each of the plurality of first opening portions 153 based on the first direction DR1 can have concave shapes. For example, a minor axis of each of the plurality of first opening portions 153 can correspond to the first direction DR1, and a major axis of each of the plurality of first opening portions 153 can correspond to the second direction DR2.

In addition, with reference to FIGS. 6 and 7, two opposite sides of each of the plurality of second opening portions 154 based on the first direction DR1 can have convex outer peripheral shapes, and two opposite sides of each of the plurality of second opening portions 154 based on the second direction DR2 can have concave shapes. For example, a major axis of each of the plurality of second opening portions 154 can correspond to the first direction DR1, and a minor axis of each of the plurality of second opening portions 154 can correspond to the second direction DR2.

Although specific shapes of the first opening 153 and the second opening 154 are described above with reference to FIGS. 6 and 7, the shapes of the first opening 153 and the second opening 154 are not limited thereto. For example, in some embodiments, the first opening 153 and/or the second opening 154 can have a circular shape or an oval shape. In addition, for example, in some embodiments, the first opening 153 and the second opening 154 can have a same shape.

The connection portion 155 can be disposed between one opening portion and another adjacent opening portion among the plurality of first opening portions 153 and the plurality of second opening portions 154.

In other words, the plurality of opening portions 153 and 154 disposed in the second part 152 of the metal plate 150 can be disposed to be spaced apart from one another, and the connection portions 155 can be disposed between the plurality of opening portions 153 and 154.

The connection portions 155 can serve to maintain the shape of the second part 152 of the metal plate 150.

The connection portions 155 disposed in the second part 152 of the metal plate 150 can be integrated.

One end of the connection portion 155 can be connected to the first part 151 of the metal plate 150. Therefore, the first part 151 and the second part 152 of the metal plate 150 can be integrated.

The other end of the connection portion 155 can be connected to the rim portion 158.

Specifically, the other end of the connection portion 155 can be connected to the first rim portion 156 in the first sub-area 152a of the second part 152 of the metal plate 150.

In addition, the other end of the connection portion 155 can be connected to the second rim portion 157 in the second sub-area 152b of the second part 152 of the metal plate 150.

The second part 152 of the metal plate 150 can include the plurality of first rim portions 156.

Specifically, the second part 152 of the metal plate 150 can include four first rim portions 156. In this case, the four first rim portions 156 can be disposed one by one in the first sub-areas 152a.

In other words, the metal plate 150 can include four first sub-areas 152a, and one first rim portion 156 can be disposed in one first sub-area 152a.

The second part 152 of the metal plate 150 can include the plurality of second rim portions 157.

Specifically, the second part 152 of the metal plate 150 can include the plurality of second sub-areas 152b. For example, the second part 152 of the metal plate 150 can include four second sub-areas 152b.

Further, the plurality of second sub-areas 152b can each include the plurality of second rim portions 157.

The number of second rim portions 157 included in the metal plate 150 can be larger than the number of first rim portions 156.

In addition, a length of each of the plurality of first rim portions 156 can be larger than a length (e.g., a first length L1) of each of the plurality of second rim portions 157. In this case, the length of each of the plurality of first rim portions 156 and the length of each of the plurality of second rim portions 157 can refer to shortest straight lengths in a direction in which a major axis of each of the rim portions 158 extends.

For example, in at least one second bending area BA2, the plurality of second rim portions 157 included in the second part 152 of the metal plate 150 can be disposed to be spaced apart from one another, and thereby it is possible to inhibit the metal plate 150 from being wrinkled by compressive stress applied to the metal plate 150 by the bending area BA.

For example, the second rim portion 157, which is disposed at one side of the first rim portion 156 among the plurality of second rim portions 157, can meet the first rim portion 156.

For another example, the second rim portion 157, which is disposed at one side of the first rim portion 156 among the plurality of second rim portions 157, can be disposed to be spaced apart from the first rim portion 156.

Therefore, it is possible to further inhibit the metal plate 150 from being wrinkled by compressive stress applied to the metal plate 150 by the bending area BA.

Specifically, in case that the metal plate 150 is bent, compressive stress is applied to the metal plate 150 while the metal plate 150 is bent.

In particular, the compressive stress can be concentrated in the second sub-area 152b of the second part 152 of the metal plate 150 corresponding to the corner. As a radius of curvature decreases, the compressive stress applied to the second sub-area 152b of the second part 152 of the metal plate 150 increases.

In addition, the compressive stress, which is applied to the second rim portion 157 corresponding to an outermost periphery of the second sub-area 152b of the second part 152 of the metal plate 150, can increase.

In this case, a defect, such as a wrinkle, occurs on the metal plate 150.

In case that the metal plate 150 is wrinkled, there is a problem in that the wrinkle is visually recognized, and the quality of the display device 100 deteriorates.

In the display device 100 according to the embodiment of the present disclosure, the plurality of second rim portions 157 disposed in the second sub-area 152b of the second part 152 of the metal plate 150 are disposed to be spaced apart from one another, such that compressive stress is dispersed to the plurality of second rim portions 157, which can inhibit the metal plate 150 from being wrinkled.

Therefore, the visibility of the display device 100 can be improved.

One side of each of the plurality of first rim portions 156 and one side of each of the plurality of second rim portions 157 can be connected to the connection portion 155.

Specifically, the connection portions 155 can include a plurality of first sub-connection portions 155a and a plurality of second sub-connection portions 155b.

The plurality of first sub-connection portions 155a can be disposed to be spaced apart from one another and extend in the first direction DR1.

The plurality of second sub-connection portions 155b can be disposed to be spaced apart from one another and extend in the second direction DR2.

The plurality of first sub-connection portions 155a and the plurality of second sub-connection portions 155b can have line shapes in which concave areas and convex areas are disposed alternately.

For example, the plurality of first sub-connection portions 155a can have line shapes in which concave areas and convex areas are disposed alternately based on straight lines extending in the first direction DR1.

In addition, the plurality of second sub-connection portions 155b can have line shapes in which concave areas and convex areas are disposed alternately based on straight lines extending in the second direction DR2.

One first opening portion 153 or one second opening portion 154 can be provided at a point at which two first sub-connection portions 155a and two second sub-connection portions 155b intersect.

For example, in the area in which one first opening portion 153 is disposed, the two first sub-connection portions 155a can each include a concave area, and the two second sub-connection portions 155b can each include a convex area.

In addition, in the area in which one second opening portion 154 is disposed, the two first sub-connection portions 155a can each include a convex area, and the two second sub-connection portions 155b can each include a concave area.

The plurality of first sub-connection portions 155a and the plurality of second sub-connection portions 155b can be connected to the plurality of first rim portions 156.

Specifically, the plurality of first sub-connection portions 155a and the plurality of second sub-connection portions 155b can be connected to side surfaces of the plurality of first rim portions 156 directed toward the first part 151 of the metal plate 150.

In addition, among the plurality of first sub-connection portions 155a and the plurality of second sub-connection portions 155b, at least two sub-connection portions can be connected to each of the plurality of second rim portions 157. However, the present application is not limited thereto. For example, in some embodiments, each second rim portion 157 is connected to one sub-connection portion.

Specifically, among the plurality of first sub-connection portions 155a and the plurality of second sub-connection portions 155b, at least two sub-connection portions can be connected to side surfaces of the plurality of second rim portions 157 directed toward the first part 151 of the metal plate 150.

As described above, the plurality of first rim portions 156 and the plurality of second rim portions 157 are connected to the sub-connection portions 155a and 155b, such that the plurality of first rim portions 156 and the plurality of second rim portions 157 can be stably connected without being separated from the metal plate 150.

In particular, the second rim portion 157, which is shorter in length than the first rim portion 156, is connected to at least two sub-connection portions 155a and 155b, such that the second rim portion 157 can be further stably connected without being separated from the metal plate 150.

In addition, as illustrated in FIG. 7, a width (also referred to as “first width” hereinafter) W1 of the second rim portion 157 can be larger than a width (also referred to as “second width” hereinafter) W2 of the connection portion 155.

In this case, the first width W1 of the second rim portion 157 can refer to a shortest straight length in a direction of a minor axis of the second rim portion 157.

In addition, the second width W2 of the connection portion 155 can refer to a shortest straight length in a direction intersecting a direction in which the connection portion 155 extends. For example, the second width W2 of the first sub-connection portion 155a extending in the first direction DR1 can refer to a shortest straight length in the second direction DR2. The second width W2 of the second sub-connection portion 155b extending in the second direction DR2 can refer to a shortest straight length in the first direction DR1.

In case that the metal plate 150 includes the second part 152 corresponding to the bending area BA as described above, compressive stress, which is applied to the second rim portion 157 corresponding to the outermost periphery of the second sub-area 152b of the second part 152 of the metal plate 150, can increase.

In this case, compressive stress can cause a defect of the metal plate 150.

In case that the first width W1 of the second rim portion 157 is decreased to suppress a defect such as a wrinkle of the metal plate 150, compressive stress to be applied to the second rim portion 157 can be reduced, but there is a problem in that the second rim portion 157 is torn and separated from the metal plate 150.

Specifically, before the metal plate 150 is applied to the display device 100, the metal plate 150 can be present in a state in which a first protective film is attached to a top surface of the metal plate 150 by means of a bonding layer, and a second protective film is disposed on a rear surface of the metal plate 150.

The metal plate 150 can be applied to the display device 100 after the first protective film attached to the top surface of the metal plate 150 is removed and the second protective film on the rear surface is removed.

In case that the first width W1 of the second rim portion 157 is small, the second rim portion 157 can be separated from the plurality of connection portions 155 during a process of removing the first protective film.

In case that the second rim portions 157 are separated from the plurality of connection portions 155 as described above, the metal plate 150 is deformed in shape, which causes a problem in that moisture permeates from the metal plate 150.

Therefore, the rigidity needs to be ensured to inhibit the second rim portions 157 from being torn and separated from the metal plate 150 in a step of removing the first protective film.

In the metal plate 150 of the display device 100 according to the embodiment of the present disclosure, the first width W1 of the second rim portion 157 is larger than the second width W2 of the connection portion 155, such that the rigidity of the second rim portion 157 can be ensured.

In addition, as the first width W1 of the second rim portion 157 increases, compressive stress to be applied to the second rim portion 157 increases when the metal plate 150 is bent, which can cause a defect such as a wrinkle of the metal plate 150.

In the metal plate 150 of the display device 100 according to the embodiment of the present disclosure, the second rim portions 157 disposed in the second bending area BA2 are not integrated, but the plurality of second rim portions 157 are disposed to be spaced apart from one another. Therefore, it is possible to disperse the compressive stress concentrated on the second rim portion 157 of the metal plate 150.

Therefore, the structure, in which the second rim portion 157 is disposed to be spaced apart from another adjacent second rim portion 157 in the second bending area BA2, can suppress a defect caused by compressive stress even though the first width W1 of the second rim portion 157 is larger than the second width W2 of the connection portion 155.

In addition, the second rim portion 157 can have the first length L1 that provides the effect of making it easy to bend the second sub-area 152b of the metal plate 150 and inhibiting the metal plate 150 from being separated even though an external force is applied.

In this case, the first length L1 can refer to a shortest length in the direction of the major axis of the second rim portion 157.

Specifically, with reference to FIG. 7, the first length L1 of the second rim portion 157 can be larger than a third length L3 made by adding the second widths W2 of the two connection portions 155 to a second length L2 that is a length of the minor axis of the first opening portion 153.

In addition, the first length L1 of the second rim portion 157 can be smaller than a length that is twice the third length L3.

In case that the first length L1 of the second rim portion 157 is smaller than the third length L3, there can occur a problem in that the second rim portion 157 is torn during the process of removing the first protective film attached to the top surface of the metal plate 150.

However, the first length L1 of the second rim portion 157 of the metal plate 150 included in the display device 100 according to the embodiment of the present disclosure is larger than the third length L3, which can ensure mechanical rigidity suitable to inhibit the connection portions 155 from being separated during the process of removing the first protective film attached to the top surface of the metal plate 150.

In addition, in case that the first length L1 of the second rim portion 157 is larger than a length that is twice the third length L3, compressive stress to be applied to the second rim portion 157 can increase.

In addition, the outermost periphery of the second sub-area 152b of the metal plate 150, in which the plurality of second rim portions 157 are disposed, needs to have a curved shape in a plan view. However, an outermost peripheral shape of the second sub-area 152b can become closer to a straight line shape as the first length L1 of the second rim portion 157 increases.

In other words, curve continuity decreases as the first length L1 of the second rim portion 157 increases, which can make it difficult to manufacture the metal plate 150 with a desired shape.

However, the first length L1 of the second rim portion 157 of the metal plate 150 included in the display device 100 according to the embodiment of the present disclosure is equal to or shorter than twice of the third length L3, such that compressive stress to be applied to the second rim portion 157 can be reduced, and the metal plate 150 with a desired shape can be easily manufactured.

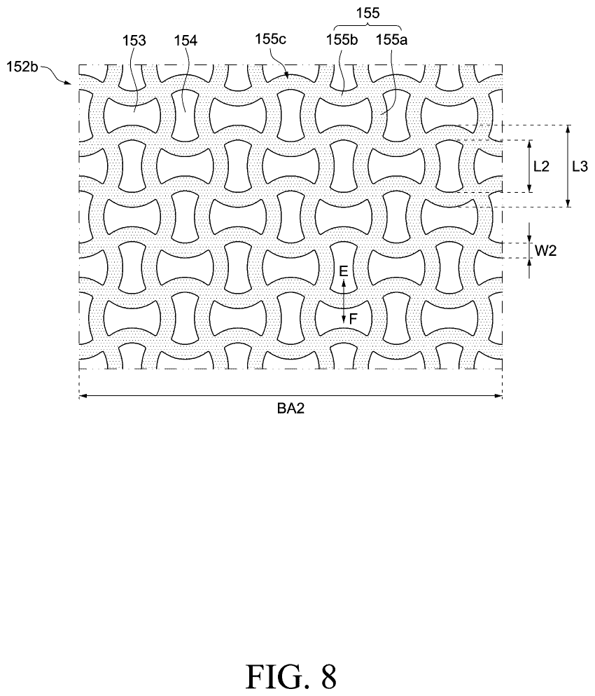

FIG. 8 is a view illustrating a part of a top surface of the connection portion disposed in the second sub-area of the second part of the metal plate included in the display device according to the embodiment of the present disclosure.

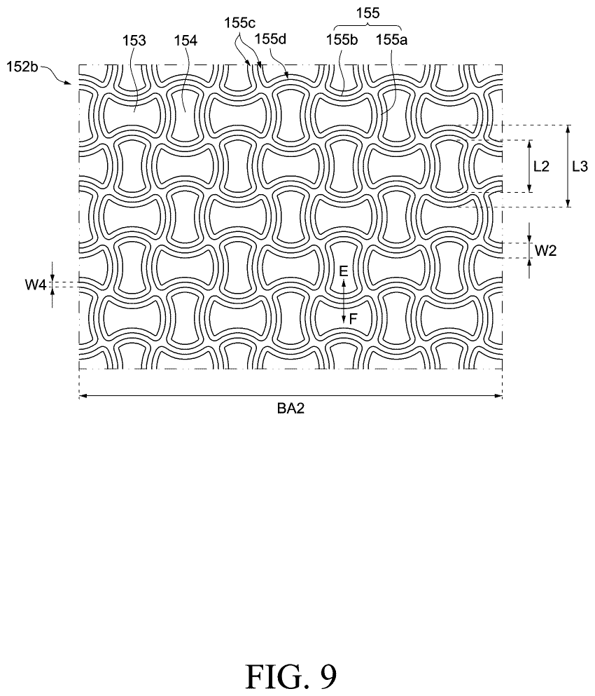

FIG. 9 is a view illustrating a part of a rear surface of the connection portion disposed in the second sub-area of the second part of the metal plate included in the display device according to the embodiment of the present disclosure.

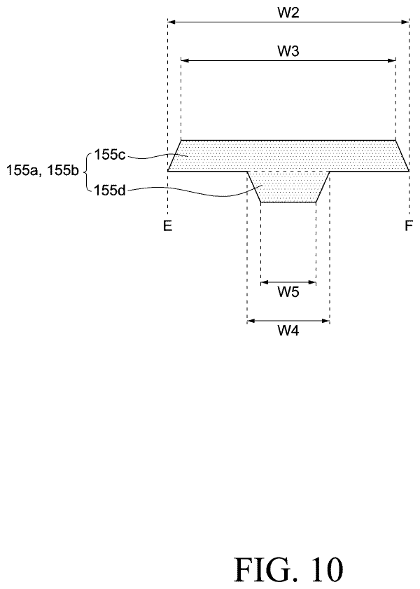

FIG. 10 is a cross-sectional view taken along line E-F in FIG. 8.

With reference to FIGS. 8 to 10, the second sub-area 152b of the second part 152 of the metal plate 150 can include the plurality of first opening portions 153, the plurality of second opening portions 154, and the connection portions 155.

The connection portions 155 disposed in the second sub-area 152b of the second part 152 of the metal plate 150 can include the plurality of first sub-connection portions 155a and the plurality of second sub-connection portions 155b.

In a cross-sectional view, the plurality of first sub-connection portions 155a and the plurality of second sub-connection portions 155b can each include a first pattern portion 155c, and a second pattern portion 155d extending from a rear surface of the first pattern portion 155c.

When the area, in which the plurality of first sub-connection portions 155a and the plurality of second sub-connection portions 155b are disposed in the second sub-area 152b of the second part 152 of the metal plate 150, is viewed from above, a top surface of the first pattern portion 155c of each of the plurality of first sub-connection portions 155a and the plurality of second sub-connection portions 155b can be visible, as illustrated in FIG. 8.

When the area, in which the plurality of first sub-connection portions 155a and the plurality of second sub-connection portions 155b are disposed in the second sub-area 152b of the second part 152 of the metal plate 150, is viewed from below, a part of a rear surface of the first pattern portion 155c and an entire rear surface of the second pattern portion 155d of each of the plurality of first sub-connection portions 155a and the plurality of second sub-connection portions 155b can be visible, as illustrated in FIG. 9.

For example, in a cross-sectional view, a minimum width of the first pattern portion 155c is larger than a maximum width of the second pattern portion 155d. As an example, In a cross-sectional view, widths W2 and W3 of the first pattern portion 155c can be larger than widths W4 and W5 of the second pattern portion 155d.

Specifically, a third width W3, which is a width of the top surface of the first pattern portion 155c, and the second width W2, which is a width of the rear surface of the first pattern portion 155c, can be larger than a fourth width W4, which is a width of the top surface of the second pattern portion 155d, and a fifth width W5 that is a width of the rear surface of the second pattern portion 155d.

In this case, the second width W2, the third width W3, the fourth width W4, and the fifth width W5 of the first sub-connection portion 155a can each be a shortest distance in a direction intersecting a direction in which the first sub-connection portion 155a extends, and the second width W2, the third width W3, the fourth width W4, and the fifth width W5 of the second sub-connection portion 155b can each be a shortest distance in a direction intersecting a direction in which the second sub-connection portion 155b extends.

Note that, since the width of the rear surface of the first pattern portion 155c is the same as the width of the connection portion mentioned above in the specific example shown in FIG. 10, the term “second width” is used herein to refer to the width of the rear surface of the first pattern portion 155c, and the corresponding reference numeral “W2” is used. However, in some other examples, for example, when the second width W2 is smaller than the third width W3, the width of the rear surface of the first pattern portion 155c can be different from the width of the connection portion.

A cross-sectional shape of each of the plurality of first sub-connection portions 155a and the plurality of second sub-connection portions 155b including the first pattern portions 155c and the second pattern portions 155d disposed in the second sub-area 152b can be a ‘T’ shape.

Meanwhile, the first protective film can be attached to the top surface of the first pattern portion 155c by means of the bonding layer.

Because a minimum width of the first pattern portion 155c is larger than a maximum width of the second pattern portion 155d (for example, in an example as shown in FIG. 10, the widths W2 and W3 of the first pattern portion 155c is larger than the widths W4 and W5 of the second pattern portion 155d), a force, which withstands an external force applied to remove the first protective film, can increase. Therefore, the mechanical rigidity can be ensured so that the plurality of first sub-connection portions 155a and the plurality of second sub-connection portions 155b are not separated from the first part 151 of the metal plate 150 in the step of removing the first protective film.

In addition, the maximum width of the second pattern portion 155d is smaller than minimum width of the first pattern portion 155c (for example, in an example as shown in FIG. 10, the widths W4 and W5 of the second pattern portion 155d are smaller than the widths W2 and W3 of the first pattern portion 155c), such that the bending properties of the plurality of first sub-connection portions 155a and the plurality of second sub-connection portions 155b can be improved.

Because the plurality of first sub-connection portions 155a and the plurality of second sub-connection portions 155b are disposed in the bending area BA of the display device 100, the display device 100 needs to be bent without damage to the plurality of first sub-connection portions 155a and the plurality of second sub-connection portions 155b. However, the bending properties deteriorate as the widths of the plurality of first sub-connection portions 155a and the widths of the plurality of second sub-connection portions 155b are increased.

In case that the widths of the plurality of first sub-connection portions 155a and the widths of the plurality of second sub-connection portions 155b are small in order to improve the bending properties of the plurality of first sub-connection portions 155a and the plurality of second sub-connection portions 155b, a defect in which the plurality of first sub-connection portions 155a and the plurality of second sub-connection portions 155b are torn occurs during the process of removing the first protective film attached to the top surface of the metal plate 150, as described above.

Because the widths W2 and W3 of the first pattern portion 155c of each of the first sub-connection portion 155a and the second sub-connection portion 155b of the metal plate 150 included in the display device 100 according to the embodiment of the present disclosure are larger than the widths W4 and W5 of the second pattern portion 155d, such that the first sub-connection portion 155a and the second sub-connection portion 155b can have the bending properties in the state in which the first sub-connection portion 155a and the second sub-connection portion 155b are not torn during the process of removing the first protective film attached to the top surface of the metal plate 150.

Specifically, the first pattern portions 155c can serve to allow the plurality of first sub-connection portions 155a and the plurality of second sub-connection portions 155b to ensure the mechanical rigidity, and the second pattern portions 155d can serve to allow the plurality of first sub-connection portions 155a and the plurality of second sub-connection portions 155b to ensure the bending properties.

In addition, the backplate 140 and the display panel 110 can be disposed on the top surfaces of the first pattern portions 155c.

As illustrated in FIGS. 8 to 10, the widths W2 and W3 of the first pattern portion 155c are larger than the widths W4 and W5 of the second pattern portion 155d, such that the plurality of first sub-connection portions 155a and the plurality of second sub-connection portions 155b can effectively support the backplate 140 and the display panel 110. Therefore, the display panel 110 is not warped, which can improve the reliability of the display panel 110.

In a cross-sectional view, the first pattern portion 155c can have a shape having a width that increases from the top surface to the rear surface. Therefore, the second width W2 of the rear surface of the first pattern portion 155c can be larger than the third width W3 of the top surface of the first pattern portion 155c.

However, the shape of the first pattern portion 155c is not limited thereto. For example, the second width W2 and the third width W3 of the first pattern portion 155c can be equal to each other.

In a cross-sectional view, the second pattern portion 155d can have a shape having a width that decreases from the top surface to the rear surface. Therefore, the fifth width W5 of the rear surface of the second pattern portion 155d can be smaller than the fourth width W4 of the top surface of the second pattern portion 155d.

However, the shape of the second pattern portion 155d is not limited thereto. For example, the fourth width W4 and the fifth width W5 of the second pattern portion 155d can be equal to each other.

The widths W2 and W3 of the first pattern portion 155c of each of the first sub-connection portion 155a and the second sub-connection portion 155b included in the metal plate 150 of the display device 100 according to the embodiment of the present disclosure only need to be larger than the widths W4 and W5 of the second pattern portion 155d.

Therefore, it is possible to ensure the bending properties while ensuring the mechanical rigidity of the first sub-connection portion 155a and the second sub-connection portion 155b.

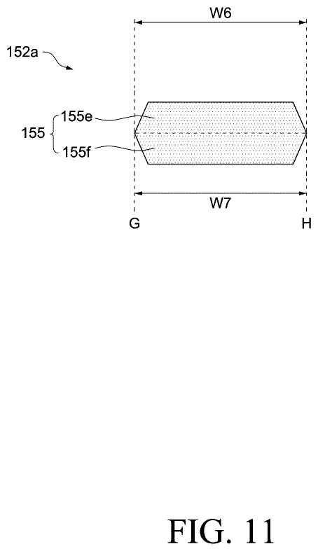

FIG. 11 is a cross-sectional view taken along line G-H in FIG. 6.

With reference to FIG. 11, a cross-sectional structure of each of the plurality of connection portions 155 disposed in the first sub-area 152a of the second part 152 of the metal plate 150 can be different from a cross-sectional structure of each of the plurality of connection portions 155 disposed in the second sub-area 152b.

Specifically, in a cross-sectional view, the plurality of connection portions 155 disposed in the first sub-area 152a can each include a third pattern portion 155e, and a fourth pattern portion 155f extending from a rear surface of the third pattern portion 155e.

When the area, in which the plurality of first sub-connection portions 155a and the plurality of second sub-connection portions 155b are disposed in the first sub-area 152a of the second part 152 of the metal plate 150, is viewed from above, a top surface of the third pattern portion 155e of each of the plurality of first sub-connection portions 155a and the plurality of second sub-connection portions 155b can be visible.

When the area, in which the plurality of first sub-connection portions 155a and the plurality of second sub-connection portions 155b are disposed in the first sub-area 152a of the second part 152 of the metal plate 150, is viewed from below, an entire rear surface of the fourth pattern portion 155f of each of the plurality of first sub-connection portions 155a and the plurality of second sub-connection portions 155b can be visible, and a part of a rear surface of the third pattern portion 155e, which does not overlap the fourth pattern portion 155f, can be visible.

In a cross-sectional view, the shape of the third pattern portion 155e and the shape of the fourth pattern portion 155f can be equal to each other. Therefore, a maximum width W6 of the third pattern portion 155e can be equal to a maximum width W7 of the fourth pattern portion 155f.

A cross-sectional shape of each of the plurality of first sub-connection portions 155a and the plurality of second sub-connection portions 155b including the third pattern portions 155e and the fourth pattern portions 155f disposed in the first sub-area 152a can be a hexagonal shape. However, the present disclosure is not limited thereto.

Meanwhile, a minimum width of the first pattern portion 155c (see FIG. 10) disposed in the second sub-area 152b (such as the third width W3 in the example as shown in FIG. 10) can be larger than a sixth width W6 and a seventh width W7 of the third pattern portion 155e and the fourth pattern portion 155f disposed in the first sub-area 152a. For example, the third width W3 can be 1.8 times larger than the sixth width W6 and the seventh width W7. However, the present disclosure is not limited thereto.

In addition, the sixth width W6 and the seventh width W7 of the third pattern portion 155e and the fourth pattern portion 155f disposed in the first sub-area 152a can be larger than a minimum width of the second pattern portion 155d (see FIG. 10) disposed in the second sub-area 152b (such as the fifth width W5 in the example as shown in FIG. 10). For example, the fifth width W5 can be a length that is 0.75 times the sixth width W6 and the seventh width W7. However, the present disclosure is not limited thereto.

As described above, the cross-sectional shapes of the plurality of first sub-connection portions 155a and the plurality of second sub-connection portions 155b disposed in the first sub-area 152a of the metal plate of the display device according to the embodiment of the present disclosure can be different from the cross-sectional shapes of the plurality of first sub-connection portions 155a and the plurality of second sub-connection portions 155b disposed in the second sub-area 152b.

Specifically, the third width W3 of the first pattern portion 155c (see FIG. 10) of each of the plurality of first sub-connection portions 155a and the plurality of second sub-connection portions 155b disposed in the second sub-area 152b of the metal plate 150, in which compressive stress is concentrated, is larger than the fifth width W5 of the second pattern portion 155d (see FIG. 10) and the sixth width W6 and the seventh width W7 of the third pattern portion 155e and the fourth pattern portion 155f disposed in the first sub-area 152a, which can suppress the occurrence of a defect of the metal plate 150 in the second sub-area 152b caused by compressive stress and improve the mechanical rigidity.

In addition, the fifth width W5 of the second pattern portion 155d (see FIG. 10) of each of the plurality of first sub-connection portions 155a and the plurality of second sub-connection portions 155b disposed in the second sub-area 152b is smaller than the third width W3 of the first pattern portion 155c (see FIG. 10) and the sixth width W6 and the seventh width W7 of the third pattern portion 155e and the fourth pattern portion 155f disposed in the first sub-area 152a, such that the third width W3 of the first pattern portion 155c (see FIG. 10) is large, which can suppress a deterioration in bending properties. Further, the plurality of first sub-connection portions 155a and the plurality of second sub-connection portions 155b can ensure the bending properties even in the second sub-area 152b.

However, the structure of the metal plate 150 of the display device according to the embodiment of the present disclosure is not limited thereto. For example, the plurality of first sub-connection portions 155a and the plurality of second sub-connection portions 155b disposed in the first sub-area 152a can be identical in cross-sectional shapes to the plurality of first sub-connection portions 155a and the plurality of second sub-connection portions 155b disposed in the second sub-area 152b.

The example embodiments of the present disclosure can also be described as follows:

According to an aspect of the present disclosure, there is provided a display device. The display device includes a display panel comprising a non-bending area and a bending area and a metal plate disposed below the display panel. The bending area includes a first bending area corresponding to a lateral portion of the non-bending area and a second bending area corresponding to a corner of the non-bending area. The metal plate includes a first part disposed in the non-bending area and a second part disposed in the bending area. The second part includes a plurality of first rim portions disposed in the first bending area and a plurality of second rim portions disposed in the second bending area. The plurality of second rim portions is disposed to be spaced apart from one another in at least one second bending area.

The second part can include four first bending areas, and the first rim portions are disposed one by one in the four first bending areas.

The first rim portion and the second rim portion can be disposed to be spaced apart from each other, and a length of one first rim portion is longer than a length of one second rim portion.

The metal plate can include four second bending areas, and the plurality of second rim portions are disposed in the four second bending areas.

The display device can further include connection portions connected to one side of each of the plurality of first rim portions and one side of each of the plurality of second rim portions. The connection portions can include a plurality of first sub-connection portions extending in a first direction and a plurality of second sub-connection portions extending in a second direction intersecting the first direction.

At least two sub-connection portions, among the plurality of first sub-connection portions and the plurality of second sub-connection portions, can be connected to one side of each of the plurality of second rim portions.

the plurality of first sub-connection portions and the plurality of second sub-connection portions each can have a line shape in which concave areas and convex areas are disposed alternately.

The second part can include a plurality of first opening portions and a plurality of second opening portions, and one first opening portion or one second opening portion can be disposed in an area in which two first sub-connection portions and two second sub-connection portions intersect.

In the area in which one first opening portion is disposed, the two first sub-connection portions each can include the concave area, and the two second sub-connection portions each can include the convex area. In the area in which one second opening portion is disposed, the two first sub-connection portions each can include the convex area, and the two second sub-connection portions each can include the concave area.

A length in a direction of a major axis of the second rim portion can be longer than a length made by adding up a length of a minor axis of the first opening portion and widths of the two second sub-connection portions and shorter than twice the length made by adding up the length of the minor axis of the first opening portion and the widths of the two second sub-connection portions.

The plurality of first sub-connection portions and the plurality of second sub-connection portions can be disposed in the second bending area. A cross-section of each of the plurality of first sub-connection portions and the plurality of second sub-connection portions in the second bending area can include a first pattern portion, and a second pattern portion extending from a rear surface of the first pattern portion. A minimum width of the first pattern portion can be larger than a maximum width of the second pattern portion.

The display panel can be disposed on the first pattern portion.

The plurality of first sub-connection portions and the plurality of second sub-connection portions can be further disposed in the first bending area. A cross-sectional shape of each of the plurality of first sub-connection portions and the plurality of second sub-connection portions disposed in the first bending area can be different from a cross-sectional shape of each of the plurality of first sub-connection portions and the plurality of second sub-connection portions disposed in the second bending area.

A cross-section of each of the plurality of first sub-connection portions and the plurality of second sub-connection portions disposed in the first bending area can include a third pattern portion, and a fourth pattern portion extending from a rear surface of the third pattern portion. A maximum width of the third pattern portion and a maximum width of the fourth pattern portion can be equal to each other.

A minimum width of the first pattern portion can be larger than a maximum width of the third pattern portion and a maximum width of the fourth pattern portion, and a minimum width of the second pattern portion can be smaller than a maximum width of the third pattern portion and a maximum width of the fourth pattern portion.

The plurality of first sub-connection portions and the plurality of second sub-connection portions can be further disposed in the first bending area. A cross-section of each of the plurality of first sub-connection portions and the plurality of second sub-connection portions in the first bending area can include a fifth pattern portion, and a sixth pattern portion extending from a rear surface of the fifth pattern portion. A minimum width of the fifth pattern portion can be larger than a maximum width of the sixth pattern portion.

According to another aspect of the present disclosure, there is provided a display device. The display device includes a display panel comprising a non-bending area and a bending area and a metal plate disposed below the display panel. The bending area includes a first bending area corresponding to a lateral portion of the non-bending area and a second bending area corresponding to a corner of the non-bending area. The metal plate includes a first part disposed in the non-bending area and a second part disposed in the bending area. The second part includes a plurality of first sub-areas disposed in the first bending area and a plurality of second sub-areas disposed in the second bending area. The second part includes a plurality of first rim portions disposed in the plurality of first sub-areas and a plurality of second rim portions disposed in the plurality of second sub-areas. One first rim portion is disposed in each of the plurality of first sub-areas and the number of second rim portions is larger than the number of first rim portions.

The display device includes connection portions connected to one side of each of the plurality of first rim portions and one side of each of the plurality of second rim portions. At least two sub-connection portions, among a plurality of first sub-connection portions and a plurality of second sub-connection portions included in the connection portions, connected to one side of one second rim portion.

The plurality of first sub-connection portions and the plurality of second sub-connection portions can be disposed in the first sub-area and the second sub-area. Cross-sectional shapes of the plurality of first sub-connection portions and the plurality of second sub-connection portions disposed in the first sub-area can be different from cross-sectional shapes of the plurality of first sub-connection portions and the plurality of second sub-connection portions disposed in the second sub-area.

The cross-sectional shape of each of the plurality of first sub-connection portions and the plurality of second sub-connection portions disposed in the first sub-area can be a hexagonal shape.

The cross-sectional shape of each of the plurality of first sub-connection portions and the plurality of second sub-connection portions disposed in the second sub-area can be a ‘T’ shape.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope of the present disclosure should be construed as falling within the scope of the present disclosure.

What is claimed is:

1. A display device comprising:
a display panel comprising a non-bending area and a bending area; and
a metal plate disposed below the display panel,
wherein the bending area comprises:
a first bending area corresponding to a lateral portion of the non-bending area; and
a second bending area corresponding to a corner portion of the non-bending area,
wherein the metal plate comprises:
a first part disposed in the non-bending area; and
a second part disposed in the bending area,
wherein the second part of the metal plate comprises:
first rim portions disposed in the first bending area; and
second rim portions disposed in the second bending area, and
wherein the second rim portions are disposed to be spaced apart from one another in at least one second bending area.

2. The display device of claim 1, wherein the second part of the metal plate comprises four first bending areas, and the first rim portions are disposed one by one in the four first bending areas.

3. The display device of claim 2, wherein one first rim portion among the first rim portions and one second rim portion among the the second rim portions are disposed to be spaced apart from each other, and a length of the one first rim portion is longer than a length of the one second rim portion.

4. The display device of claim 1, wherein the metal plate comprises four second bending areas, and the second rim portions are disposed in the four second bending areas.

5. The display device of claim 1, further comprising:
connection portions connected to one side of each of the first rim portions and one side of each of the second rim portions,
wherein the connection portions comprise:
a plurality of first sub-connection portions extending in a first direction; and
a plurality of second sub-connection portions extending in a second direction intersecting the first direction.

6. The display device of claim 5, wherein at least two sub-connection portions, among the plurality of first sub-connection portions and the plurality of second sub-connection portions, are connected to one side of each of the second rim portions.

7. The display device of claim 5, wherein the plurality of first sub-connection portions and the plurality of second sub-connection portions each have a line shape in which concave areas and convex areas are disposed alternately.

8. The display device of claim 7, wherein the second part of the metal plate further comprises a plurality of first opening portions and a plurality of second opening portions, and one first opening portion or one second opening portion is disposed in an area in which two first sub-connection portions and two second sub-connection portions intersect.

9. The display device of claim 8, wherein in the area in which the one first opening portion is disposed, the two first sub-connection portions each comprise the concave area, and the two second sub-connection portions each comprise the convex area, and
wherein in the area in which the one second opening portion is disposed, the two first sub-connection portions each comprise the convex area, and the two second sub-connection portions each comprise the concave area.

10. The display device of claim 8, wherein a length in a direction of a major axis of one of the second rim portions is longer than a length made by adding up a length of a minor axis of the first opening portion and widths of the two second sub-connection portions and shorter than twice the length made by adding up the length of the minor axis of the first opening portion and the widths of the two second sub-connection portions.

11. The display device of claim 5, wherein the plurality of first sub-connection portions and the plurality of second sub-connection portions are disposed in the second bending area,
wherein a cross-section of each of the plurality of first sub-connection portions and the plurality of second sub-connection portions in the second bending area comprises a first pattern portion, and a second pattern portion extending from a rear surface of the first pattern portion, and
wherein a minimum width of the first pattern portion is larger than a maximum width of the second pattern portion.

12. The display device of claim 11, wherein the display panel is disposed on the first pattern portion.

13. The display device of claim 11, wherein the plurality of first sub-connection portions and the plurality of second sub-connection portions are further disposed in the first bending area, and
wherein a cross-sectional shape of each of the plurality of first sub-connection portions and the plurality of second sub-connection portions disposed in the first bending area is different from a cross-sectional shape of each of the plurality of first sub-connection portions and the plurality of second sub-connection portions disposed in the second bending area.

14. The display device of claim 13, wherein a cross-section of each of the plurality of first sub-connection portions and the plurality of second sub-connection portions disposed in the first bending area comprises a third pattern portion, and a fourth pattern portion extending from a rear surface of the third pattern portion, and
wherein a maximum width of the third pattern portion and a maximum width of the fourth pattern portion are equal to each other.

15. The display device of claim 14, wherein a minimum width of the first pattern portion is larger than a maximum width of the third pattern portion and a maximum width of the fourth pattern portion, and a minimum width of the second pattern portion is smaller than a maximum width of the third pattern portion and a maximum width of the fourth pattern portion.

16. The display device of claim 11, wherein the plurality of first sub-connection portions and the plurality of second sub-connection portions are further disposed in the first bending area,
wherein a cross-section of each of the plurality of first sub-connection portions and the plurality of second sub-connection portions in the first bending area comprises a fifth pattern portion, and a sixth pattern portion extending from a rear surface of the fifth pattern portion, and
wherein a minimum width of the fifth pattern portion is larger than a maximum width of the sixth pattern portion.

17. A display device comprising:
a display panel comprising a non-bending area and a bending area; and
a metal plate disposed below the display panel,
wherein the bending area comprises:
a first bending area corresponding to a lateral portion of the non-bending area; and
a second bending area corresponding to a corner portion of the non-bending area,
wherein the metal plate comprises:
a first part disposed in the non-bending area; and
a second part disposed in the bending area,
wherein the second part of the metal plate comprises:
a plurality of first sub-areas disposed in the first bending area; and
a plurality of second sub-areas disposed in the second bending area,
wherein the second part of the metal plate further comprises:
a plurality of first rim portions disposed in the plurality of first sub-areas; and
a plurality of second rim portions disposed in the plurality of second sub-areas,
wherein one first rim portion among the plurality of first rim portions is disposed in each of the plurality of first sub-areas, and
wherein the number of the second rim portions is larger than the number of the first rim portions.

18. The display device of claim 17, further comprising:
connection portions connected to one side of each of the plurality of first rim portions and one side of each of the plurality of second rim portions,
wherein at least two sub-connection portions, among a plurality of first sub-connection portions and a plurality of second sub-connection portions included in the connection portions, connected to one side of one second rim portion among the plurality of second rim portions.

19. The display device of claim 18, wherein the plurality of first sub-connection portions and the plurality of second sub-connection portions are disposed in the first sub-area and the second sub-area, and
wherein cross-sectional shapes of the plurality of first sub-connection portions and the plurality of second sub-connection portions disposed in the first sub-area are different from cross-sectional shapes of the plurality of first sub-connection portions and the plurality of second sub-connection portions disposed in the second sub-area.

20. The display device of claim 19, wherein the cross-sectional shape of each of the plurality of first sub-connection portions and the plurality of second sub-connection portions disposed in the first sub-area is a hexagonal shape, and
wherein the cross-sectional shape of each of the plurality of first sub-connection portions and the plurality of second sub-connection portions disposed in the second sub-area is a ‘T’ shape.
